(19) United States
(12) Patent Application Publication
(10) Pub. No.: US 2026/0050723 A1
(43) Pub. Date: Feb. 19, 2026

(54) METHOD OF CHECKING LAYOUT DESIGN WITH MULTIPLE MATCHING ZONES

(71) Applicant: TAIWAN SEMICONDUCTOR MANUFACTURING COMPANY, LTD., Hsinchu (TW)

(72) Inventors: Yu-Te SHEN, Hsinchu (TW); Yung-Shun CHEN, Hsinchu (TW); Phoebe LIN, Hsinchu (TW); Hung-Hsiang LIN, Hsinchu (TW); Shu-Chin TAI, Hsinchu (TW); Chi-Wen CHANG, Hsinchu (TW)

(21) Appl. No.: 18/966,571

(22) Filed: Dec. 3, 2024

Related U.S. Application Data
(60) Provisional application No. 63/684,107, filed on Aug. 16, 2024.

(51) Int. Cl. G06F 30/3323; G06F 30/398

(52) U.S. Cl. CPC G06F 30/3323; G06F 30/398

(57) ABSTRACT

A method includes finding repeated layout patterns at least in a part of a layout design of an integrated circuit, identifying multiple layout units from the repeated layout patterns, and separating the layout design into multiple matching zones. At least two of the matching zones have different sets of matching rules. Each of the multiple layout units is in a first matching zone. The method also includes comparing a first layout unit with a second layout unit, and checking layout pattern consistency between the first layout unit and the second layout unit.

### PRIORITY CLAIM

The present application claims the priority of U.S. Provisional Application No. 63/684,107, filed Aug. 16, 2024, which is incorporated herein by reference in its entirety.

### BACKGROUND

The recent trend in miniaturizing integrated circuits (ICs) has resulted in smaller devices which consume less power yet provide more functionality at higher speeds. The miniaturization process has also resulted in more strict restriction on the layout design of the IC circuits. In the design of the ICs, predesigned cells having well-defined functions are stored in cell libraries. When designing an integrated circuit, the predesigned cells are retrieved from the cell libraries and placed into designated locations in a layout of the integrated circuit. Conductive lines are designed in the layout to connect the predesigned cells to provide the routing. During the layout design, the selection of the designated locations for the predesigned cells and the associated routing often need to consider the optimization of the speed or the optimization of the power consumption for various components in the ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a layout design of an integrated circuit, in accordance with some embodiments.

FIGS. 2A-2B are schematic diagrams of repetitive electric circuits each implemented in a layout unit, in accordance with some embodiments.

FIG. 3A is a table listing some examples of the matching rules in the three example matching zones of FIG. 1, in accordance with some embodiments.

FIG. 3B is a drawing of the mismatch variation plotted against the horizontal distance from the center of the innermost matching zone, in accordance with some embodiments.

FIGS. 4A-4C are various designs of matching zones, in accordance with some embodiments.

FIG. 5 is a schematic diagram of a matrix of layout units in a matching zone, in accordance with some embodiments.

FIGS. 6A1-6A2 and FIGS. 6B1-6B2 are schematic diagrams of some layout units having fatal rule violations, in accordance with some embodiments.

FIG. 7A is a schematic diagram of a layout design of an integrated circuit having a matrix of layout units in a matching zone, in accordance with some embodiments.

FIG. 7B is a schematic diagram of a layout design of an integrated circuit having layout units arranged in multiple rectangular areas of a matching zone, in accordance with some embodiments.

FIGS. 8A-8D are schematic diagrams of layout designs of an integrated circuit having a matrix of layout units in a matching zone 800, in accordance with some embodiments.

FIG. 9A is a schematic diagram of two layout units having layout pattern consistency under a horizontal reflection symmetry operation, in accordance with some embodiments.

FIG. 9B is a schematic diagram of two layout units having layout pattern consistency under a vertical reflection symmetry operation, in accordance with some embodiments.

FIGS. 10A-10B are flowcharts of methods of processing a layout design of an integrated circuit, in accordance with some embodiments.

FIG. 11 is a flowchart of method of a design flow process for an integrated circuit, in accordance with some embodiments.

FIG. 12 is a block diagram of an electronic design automation (EDA) system in accordance with some embodiments.

FIG. 13 is a block diagram of an integrated circuit (IC) manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, materials, values, steps, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, the layout design of an integrated circuit is divided into multiple matching zones. One of the matching zones has a matrix of layout units. Each of the layout units is a circuit layout design of a same electric sub-circuit in the integrated circuit.

In one example implementation, one of the layout units is selected as a reference layout design. In response to a finding that the reference layout design is free of fatal rule violations, the reference layout design is compared with another layout unit in the matrix in a layout-versus-layout comparison process. In each iteration, one of the layout units in the matrix is chosen as a chosen layout unit, and the chosen layout unit is compared with the reference layout design to check for layout pattern consistency in the layout-versus-layout comparison process. The layout-versus-layout comparison process involves matching the layout patterns of two layout units with a symmetry operation such as a translational symmetry operation, a reflection symmetry operation, and/or a rotational symmetry operation.

In another example implementation, a row of the layout units is selected from the matrix of layout units as a reference layout design. In response to a finding that the reference layout design is free of fatal rule violations, the reference layout design is compared with another row of layout units in the matrix in a layout-versus-layout comparison process. In each iteration, one row of layout units in the matrix is chosen as a chosen row of layout units, and the chosen row of layout units is compared with the reference layout design to check for layout pattern consistency in the layout-versus-layout comparison process. The layout-versus-layout comparison process involves matching the layout patterns of two rows of layout units with a symmetry operation.

In the example implementations, executing layout-versus-layout comparison processes for finding defects in a layout design improves efficiency of the design rule check (DRC). As different matching zones are checked with different DRC process, the total time running for DRC check on the layout design is reduced.

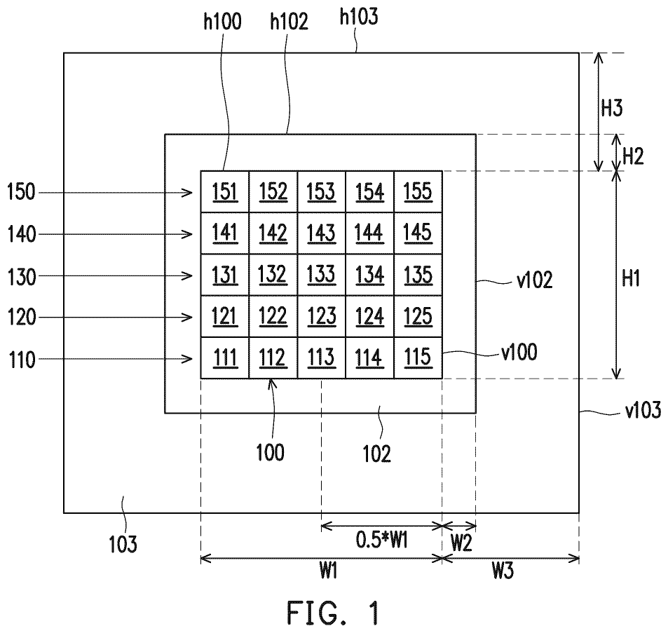

FIG. 1 is a schematic diagram of a layout design of an integrated circuit, in accordance with some embodiments. In FIG. 1, the layout design is separated into multiple matching zones such as matching zones 100, 102, and 103. The matching zone 100 is surrounded by the matching zone 102. The matching zone 102 is surrounded by the matching zone 103.

The layout design of the integrated in the matching zone 100 has repeated layout patterns. The repeated layout patterns in FIG. 1 are divided into multiple layout units which form a matrix of layout units having multiple rows of layout units (such as 110-150). The row 110 includes layout units 111-115, the row 120 includes layout units 121-125, the row 130 includes layout units 131-135, the row 140 includes layout units 141-145, and the row 150 includes layout units 151-155. Each layout unit in the matrix of layout units is a circuit layout design of a same electric circuit. Examples of the same electric circuit include an element device (such as a transistor) or a sub-circuit in the integrated circuit.

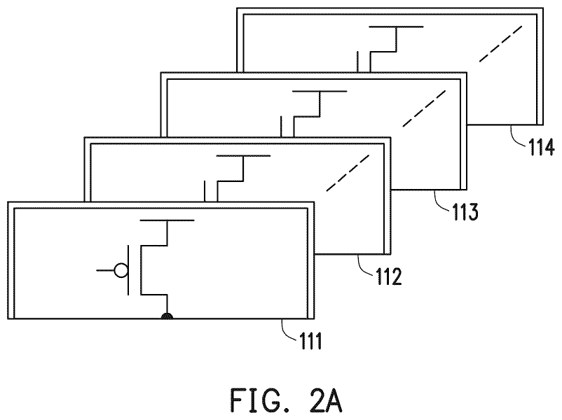

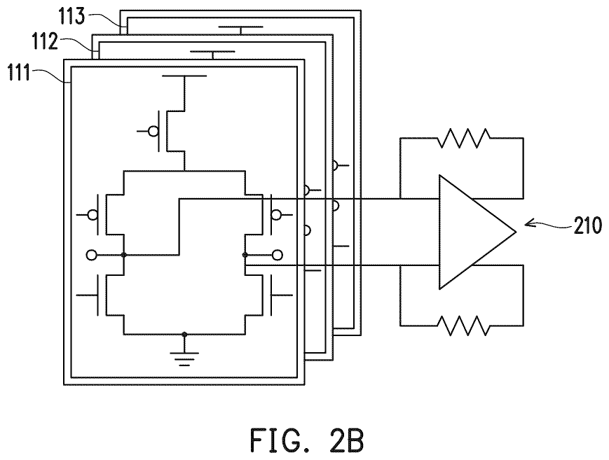

FIGS. 2A-2B are schematic diagrams of repetitive electric circuits each implemented in a layout unit, in accordance with some embodiments. In FIG. 2A, the repetitive electric circuit implemented in each of the layout units 111, 121, 131, and 141 are explicitly shown, while the repetitive electric circuit for the remaining layout units in the matrix of layout units is the same (which is not explicitly shown). The repetitive electric circuit in FIG. 2A for each layout unit is a transistor. In one example implementation, the matrix of layout units having a transistor in each layout unit forms part of a capacitive bank. In FIG. 2B, the repetitive electric circuit implemented in each of the layout units 111, 112, and 113 are explicitly shown, while the repetitive electric circuit for the remaining layout units in the matrix of layout units is the same (which is not explicitly shown). In one example implementation, the repetitive electric circuit in FIG. 2B for each layout unit is a comparator circuit, and the comparator circuits in the layout units 111, 112, and 113 are connected to a summation circuit 210 in an analog-to-digital converter. Thus, each of the layout units 111, 112, and 113 has therein a comparator circuit which is a sub-circuit of an analog-to-digital converter. In some implementations, the layout design of the summation circuit 210 in FIG. 2B is implemented in the matching zone 103 (as shown in FIG. 1) which has a different set of matching rules than the matching zone 100.

In FIG. 1, the matching zones 100, 102, and 103 have different sets of matching rules. In some implementations, as the matching rules for matching zones 100 and 103 are compared, each matching rule for the matching zone 103 is also a matching rule for the matching zone 100 while at least one matching rule for the matching zone 100 is not a matching rule for the matching zone 103. In some implementations, as the matching rules for matching zones 100, 102, and 103 are compared, each matching rule for the matching zone 103 is also a matching rule for the matching zone 102 while at least one matching rule for the matching zone 100 is not a matching rule for the matching zone 102.

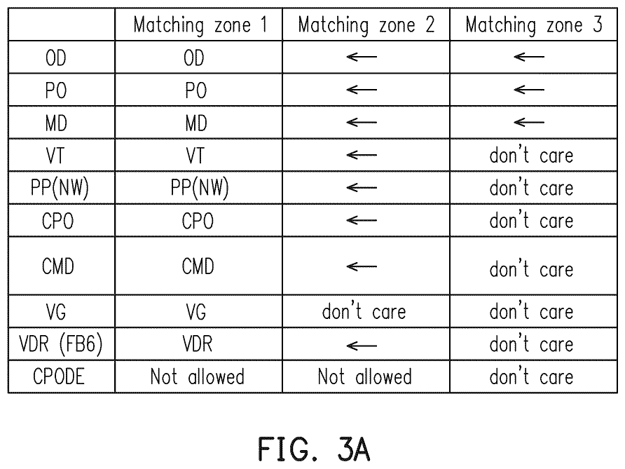

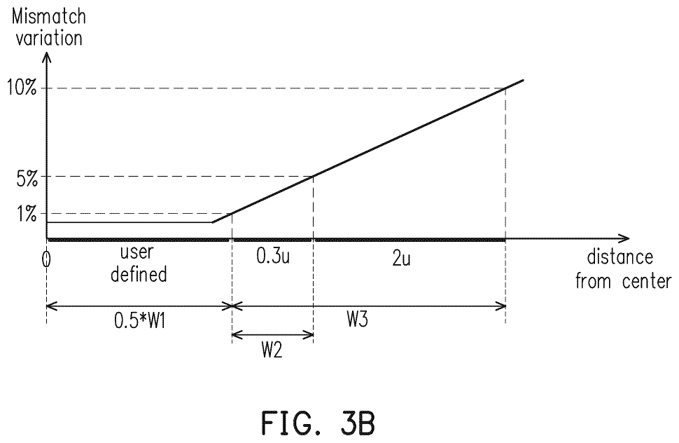

FIG. 3A is a table listing some examples of the matching rules in the three example matching zones of FIG. 1, in accordance with some embodiments. The example matching rules listed in the table of FIG. 3A are labeled with rule identifiers such as OD, PO, MD, VT, NP, PP(NW), CPO, CMD, VG, VDR(FB6), and CPODE. The set of matching rules for the matching zone 100 includes all example matching rules listed in the table. That is, all of the matching rules OD, PO, MD, VT, NP, PP(NW), CPO, CMD, VG, VDR(FB6), and CPODE are enforced for the layout designs in the matching zone 100. The set of matching rules for the matching zone 102 is a subset of the set of matching rules for the matching zone 100. For example, while the matching rule VG is a matching rule for the matching zone 100, the matching rule VG is not a matching rule for the matching zone 102. Similarly, the set of matching rules for the matching zone 103 is a subset of the set of matching rules for the matching zone 102. For example, none of the matching rules VT, NP, PP(NW), CPO, CMD, VG, VDR(FB6), and CPODE is a matching rule for the matching zone 103, but the matching rules VT, NP, PP(NW), CPO, CMD, and VDR(FB6) are matching rules for the matching zone 102.

In some embodiments, the transistors in each of the matching zones are implemented in one or more active-region structures. In some implementations, FinFET transistors are implemented in an active-region structure having fin structures. In some implementations, nano-sheet transistors are implemented in a nano-sheet active-region structure. In some implementations, nano-wire transistors are implemented in a nano-wire active-region structure.

In some embodiments, a transistor having the channel in the active-region structure is implemented with a gate-conductor intersecting the active-region structure. The length of the channel is related to a width of the gate-conductor, and the width of the channel is related to a width of the active-region structure or the number of fins in the active-region structure. While the gate-conductor intersecting the active-region structure forms a gate terminal of the transistor, the source terminal and the drain terminal of the transistor are implemented with terminal-conductors intersecting the active-region structure.

In some embodiments, the active-region structures in the integrated circuit extend in a first direction such as the X-direction, the gate-conductors and the terminal-conductors in the integrated circuit extend in a second direction such as the Y-direction. The layout patterns for specifying the active-region structures are checked with the matching rule labeled OD in the table of FIG. 3A. The layout patterns for specifying the gate-conductors are checked with the matching rule labeled PO in the table of FIG. 3A. The layout patterns for specifying the terminal-conductors are checked with the matching rule labeled MD in the table of FIG. 3A. In some embodiments, the layout patterns for specifying a separation between two gate-conductors aligned in the Y-direction are checked with the matching rule labeled CPO, and the layout patterns for specifying a separation between two terminal-conductors aligned in the Y-direction are checked with the matching rule labeled CMD.

In some embodiments, the gate-conductors and the terminal-conductors are covered with an interlayer dielectric. At least one of the gate-conductors is connected to a conducting line overlying the interlayer dielectric though a via connector VG. At least one of the terminal-conductors is connected to a conducting line overlying the interlayer dielectric though a via connector VD, and as a special case, one of the terminal-conductors is connected to a power rail overlying the interlayer dielectric though a via connector VDR. The layout patterns for specifying the via connector VG are checked with the matching rule labeled VG in the table of FIG. 3A. The layout patterns for specifying the via connector VDR are checked with the matching rule labeled VDR in the table of FIG. 3A.

In some embodiments, isolation regions are implemented in the active-region structures. An isolation region in an active-region structure separates the active-region into a first part and a second part, and because of the isolation region, the active regions in the first part of the active-region structure are isolated from the active regions in the second part of the active-region structure. The layout patterns for specifying isolation regions in the active-region structures are checked with the matching rule labeled CPODE in the table of FIG. 3A.

In some embodiments, transistors with various threshold voltages (such as, standard threshold transistors, low threshold transistors, high threshold transistors) are implemented in the integrated circuit. The threshold voltages of the transistors are checked with the matching rule labeled VT in the table of FIG. 3A. In some embodiments, PMOS transistors are implemented in PMOS active-region structures, and the PMOS active-region structures are implemented in an n-type well. In some embodiments, NMOS transistors are implemented in NMOS active-region structures, and the NMOS active-region structures are implemented in a p-type well. The layout patterns for specifying the n-type well and the p-type well are checked with the matching rules labeled NP and PP.

In FIG. 3A, the sets of matching rules for the matching zones 100, 102, and 103 of FIG. 1 are listed in the table. There are more matching rules for the matching zone 100 than matching rules for the matching zone 102. There are more matching rules for the matching zone 102 than matching rules for the matching zone 103. Circuit cells which require better uniformity in electric properties or require better geometric matching between device elements are positioned in the innermost matching zone (such as the matching zone 100). Circuit cells with relaxed uniformity or matching requirements are positioned in the outer matching zone (such as the matching zone 103). Circuit cells positioned in the mid matching zone (i.e., 102) have stronger uniformity or matching requirements than the circuit cells in the outer matching zone (i.e., 103) but have weaker uniformity or matching requirements than the circuit cells in the innermost matching zone (i.e., 100).

In FIG. 1, various dimensions labeled for the matching zones include widths W1, W2, and W3 and heights H1, H2, and H3. In some embodiments, the width W1 of the matching zone 100 and the height H1 of the matching zone 100 are defined by a user. In some embodiments, a width W2 of the matching zone 102 (as measured between a vertical boundary v100 of the matching zone 100 and a vertical boundary v102 of the matching zone 102) is several contacted-poly-pitch (CPP). For example, in one implementation, the width W2 is 6 CPP, where one CPP is the pitch distance between two adjacent gate-conductors. In some embodiments, a height H2 of the matching zone 102 (as measured between a horizontal boundary h100 of the matching zone 100 and a horizontal boundary h102 of the matching zone 102) is one cell height. In some implementations, the height H2 is the height of a standard cell which has two active-region structures each extending in the X-direction. In some implementations, the height H2 is the height of a double-height cell which has four active-region structures each extending in the X-direction.

In some embodiments, a width W3 of the matching zone 103 (as measured between a vertical boundary v100 of the matching zone 100 and a vertical boundary v103 of the matching zone 103) depends upon the value of the width W1 of the matching zone 100 and the value of the height H1 of the matching zone 100. A height H3 of the matching zone 103 (as measured between a horizontal boundary h100 of the matching zone 100 and a horizontal boundary h103 of the matching zone 103) also depends upon the value of the width W1 and the value of the height H1. In one example, one or both of the width W1 and the height H1 are larger than 5 micrometers, and each of the width W3 and the height H3 of the matching zone 103 is 5 micrometers. In another example, both the width W1 and the value of the height H1 are smaller than 5 micrometers, and each of the width W3 and the height H3 of the matching zone 103 is 2 micrometers.

In the integrated circuit of FIG. 1, the mismatch variations of electric properties often increase as the position of a circuit cell moves further away from the center of the innermost matching zone (i.e. 100). In FIG. 1, the horizontal distance from the center of the matching zone 100 to the vertical boundary v100 of the matching zone 100 is 0.5*W1, the horizontal distance from the center of the matching zone 100 to the vertical boundary v102 of the matching zone 102 is 0.5*W1+W2, and the horizontal distance from the center of the matching zone 100 to the vertical boundary v103 of the matching zone 103 is 0.5*W1+W3.

FIG. 3B is a drawing of the mismatch variation plotted against the horizontal distance from the center of the innermost matching zone, in accordance with some embodiments. A shown in FIG. 3B, the mismatch variation in the matching zone 100 remains less than 1%, the mismatch variation in the matching zone 200 is between 1% and 5%, and the mismatch variation in the matching zone 200 is between 5% and 10%. Thus, circuit cells in matching zone 100 have better uniformity in electric properties than circuit cells in matching zone 102, while circuit cells in matching zone 102 have better uniformity in electric properties than circuit cells in matching zone 103.

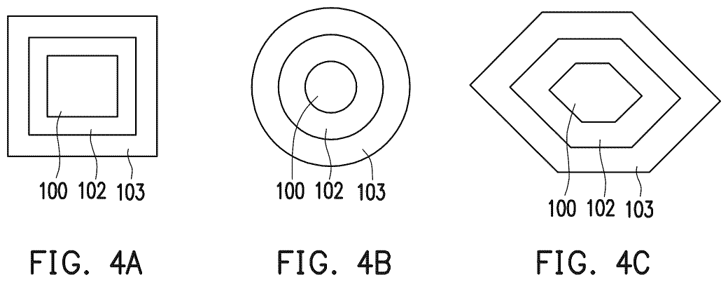

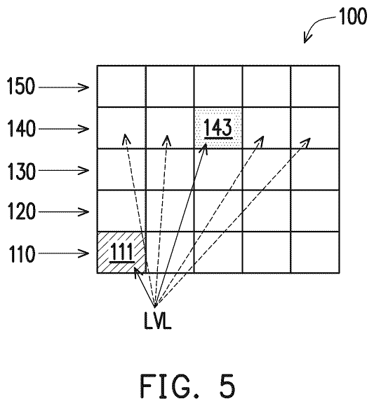

The matching zones as shown in FIG. 1 are provided as examples, other designs and arrangements of matching zones are within the contemplated scope of present disclosure. FIGS. 4A-4C are various designs of matching zones, in accordance with some embodiments. In FIG. 4A, the outer boundary of each matching zone (100, 102, or 103) has the shape of a rectangular. In FIG. 4B, the outer boundary of each matching zone (100, 102, or 103) has the shape of a circular. In FIG. 4C, the outer boundary of each matching zone (100, 102, or 103) has the shape of a polygon. In each design of matching zones in FIGS. 4A-4C, a first matching zone (e.g., 100) is surrounded by a second matching zone (e.g., 102) which is further surrounded by a third matching zone (e.g., 103).

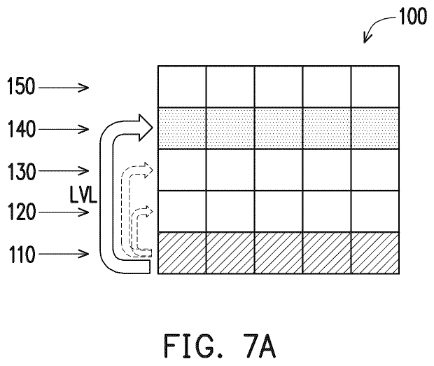

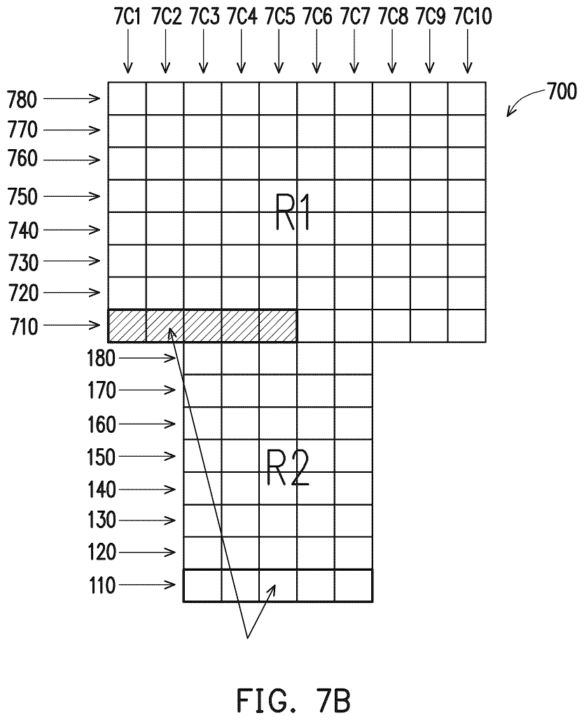

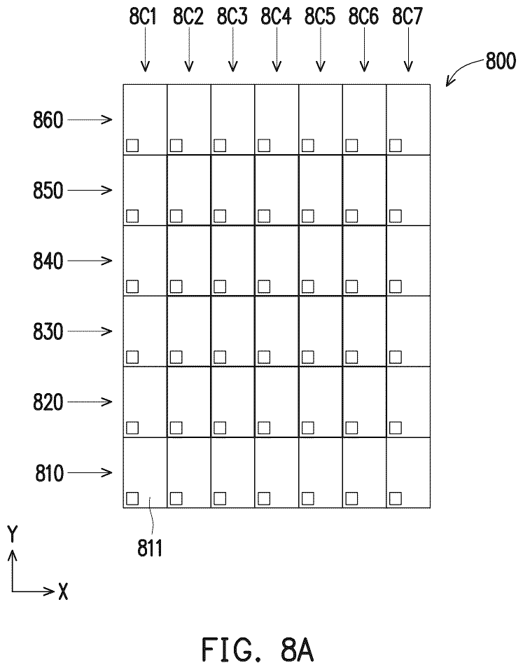

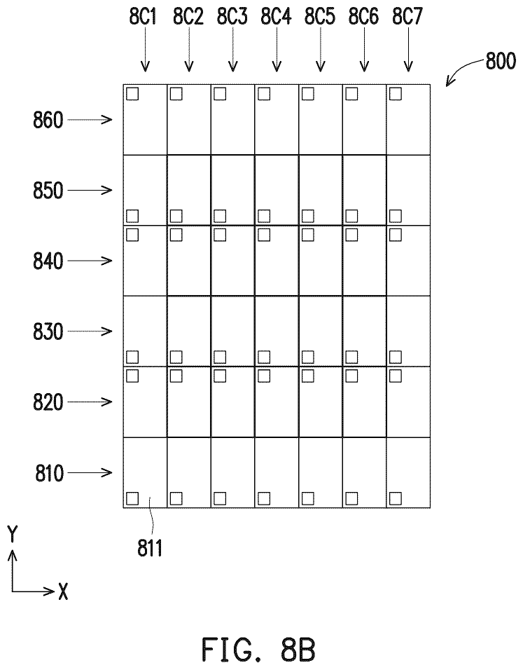

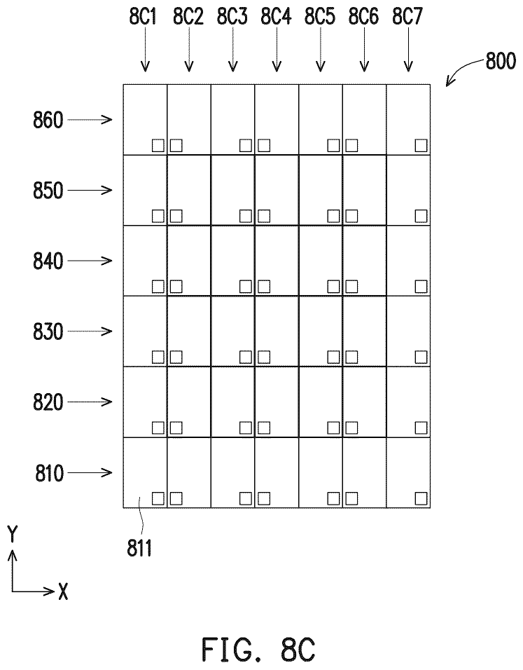

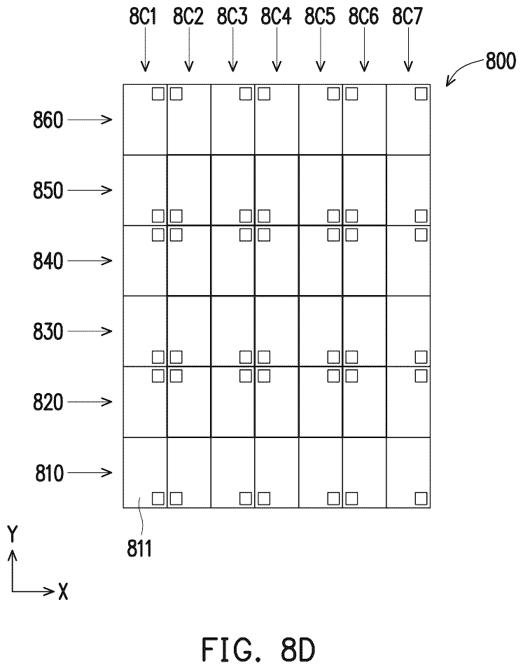

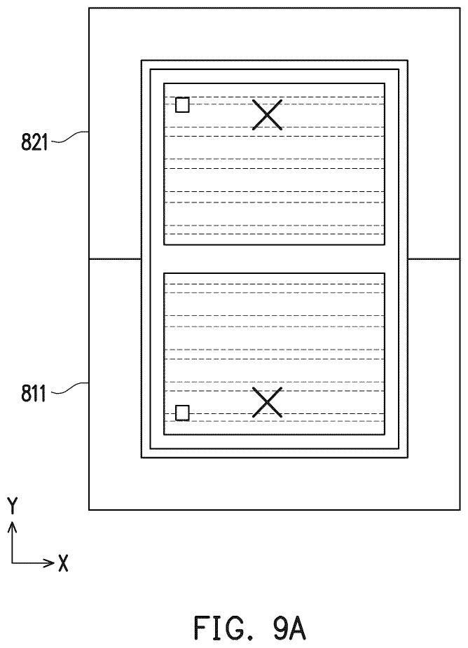

In FIG. 1, because the matching zone 100 has repeated layout patterns which are divided into multiple layout units, it becomes feasible to check some of the design rules on the layout units based on a method that involves a layout-versus-layout (“LVL”) comparison with a reference layout design. Methods involving layout-versus-layout comparison are described with reference to FIG. 5, FIGS. 7A-7B, and FIGS. 8A-8D.

FIG. 5 is a schematic diagram of a matrix of layout units in a matching zone 100, in accordance with some embodiments. In some embodiments, one of the layout units in the matching zone 100 is selected as a reference layout design, and each of the other layout units in the matching zone 100 is compared with the reference layout design to check for layout pattern consistency. In some implementations, if the layout design pattern of a chosen layout unit is found to be the same as the layout design pattern of the reference layout design, then, the chosen layout unit is consistent with the reference layout design. In some implementations, if the layout design pattern of a chosen layout unit matches the layout design pattern of the reference layout design under a symmetry operation, then, the chosen layout unit is consistent with the reference layout design. Here, the symmetry operation performed on the chosen layout or on the reference layout design includes a translational symmetry operation, a reflection symmetry operation, a rotational symmetry operation, or a combination thereof.

In the example as shown in FIG. 5, the layout unit 111 in the row 110 is selected as the reference layout design. Each of the remaining layout units (i.e., 112-115) in the row 110 is compared with the layout unit 111 to check for layout pattern consistency. Furthermore, each layout unit in other rows (such as the rows 120, 130, 140, and 150) is also compared with the layout unit 111 to check for layout pattern consistency.

Before the layout unit 111 (as the reference layout design) is compared with another layout unit to check for layout pattern consistency, the layout unit 111 is checked with design rules for fatal rule violations. The layout unit 111 (as the reference layout design) is compared with another layout unit only if no fatal rule violation is found. If the checking on the layout unit 111 with design rules finds a fatal rule violation, the layout design of the layout unit 111 is repaired to mitigate the fatal rule violation, and the layout unit 111 is again checked for fatal rule violations. This process of checking and repairing is repeated until the layout unit 111 is free from fatal rule violations.

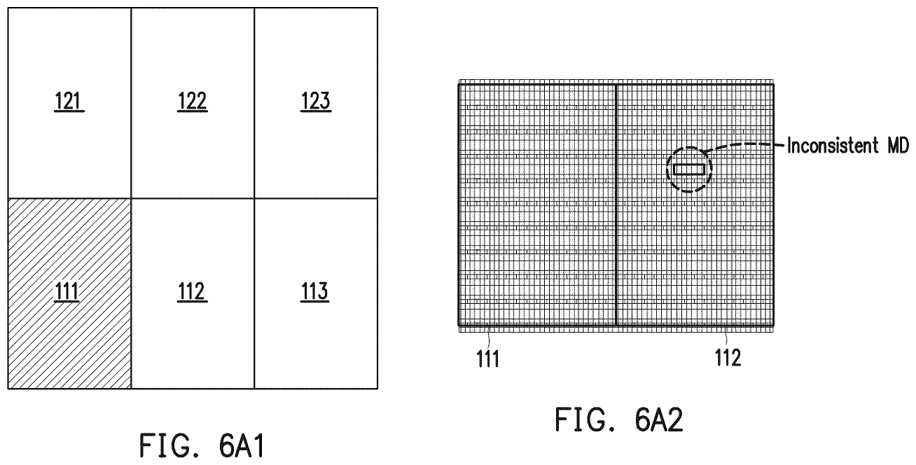

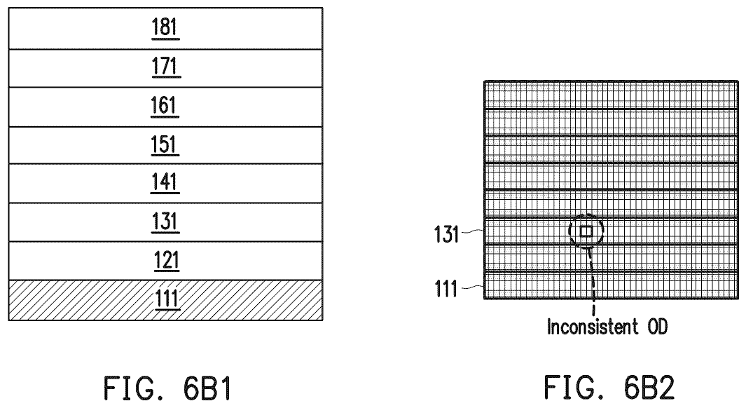

During the process of comparing a chosen layout unit with the layout unit 111, if the chosen layout unit is consistent with the reference layout design, it is then inferred that the chosen layout is also free from fatal rule violations. If the chosen layout unit is consistent with the reference layout design, the chosen layout unit is deemed to satisfy the same collection of design rules which have been satisfied by the layout unit 111 (as the reference layout design) during the prior process of checking fatal rule violations with design rules. Examples of design rule violations in layout units revealed with a layout-versus-layout comparison are shown in FIGS. 6A1-6A2 and FIGS. 6B1-6B2.

FIG. 6A1 is a schematic diagram of an arrangement of some layout units in an integrated circuit, in accordance with some embodiments. In one example, the layout units in FIG. 6A1 correspond to the layout units 111-113 of the row 110 and the layout units 121-123 of the row 120 in the matching zone 100 as shown in FIG. 1 or FIG. 5. In one implementation, the layout unit 111 in the row 110 is selected as the reference layout design. In response to a checking process which finds no fatal rule violation in the layout unit 111, each of the remaining layout units 112-113 and 121-123 of FIG. 6A1 is compared with the layout unit 111 to check for layout pattern consistency. In the example as shown in FIG. 6A2, certain layout pattern inconsistencies between the layout unit 111 and the layout unit 112 are revealed during the layout-versus-layout comparison process. The failure of the layout unit 112 to pass the layout-versus-layout comparison process is due to some inconsistent MD layout pattern specifying the terminal-conductors, and the layout unit 112 would fail design certain design rules (such as the matching rule labeled MD in FIG. 5). The schematic diagrams of FIGS. 6A1-6A2 provide an example indicating that a design rule violation in a layout unit is revealed based on a layout-versus-layout comparison process.

Similarly, the schematic diagrams of FIGS. 6B1-6B2 provide another example indicating that a design rule violation in a layout unit is revealed based on a layout-versus-layout comparison process. In each of the schematic diagrams of FIGS. 6B1-6B2, a column of layout units 111-181 in an integrated circuit is depicted. The column of layout units 111-181 is in an innermost matching zone (such as, the matching zone 100 in FIGS. 4A-4C). In some implementations, each of the layout units 111-181 is a circuit layout design of a same electric circuit (such as a sub-circuit as shown in FIG. 2B) in the integrated circuit. In one implementation, the layout unit 111 is selected as the reference layout design. In response to a checking process which finds no fatal rule violation in the layout unit 111, each of the remaining layout units 121-181 is compared with the layout unit 111 to check for layout pattern consistency. In the example as shown in FIG. 6B2, certain layout pattern inconsistencies between the layout unit 111 and the layout unit 131 are revealed during the layout-versus-layout comparison process. The failure of the layout unit 131 to pass the layout-versus-layout comparison process is due to some inconsistent OD layout pattern specifying active-region structures, and the layout unit 131 would fail design certain design rules (such as the matching rule labeled OD in FIG. 5).

In FIG. 5, each layout unit in the matching zone 100 is compared with the reference layout design (i.e., the layout unit 111) in a layout-versus-layout comparison process to check for layout pattern consistency. In an implementation where the matching zone 100 includes a matrix of layout units which has N rows and N column, to finish the checking of layout pattern consistency on all layout units in the matching zone 100, the layout-versus-layout comparison with the reference layout design is conducted about N×N times. In some scenarios, as the number N becomes large, the method (as shown in FIG. 5) of comparing each layout unit in the matching zone 100 with the reference layout design (i.e., the layout unit 111) also becomes more time consuming than some alternative methods in which a reference layout design includes more than one layout unit and in which the reference layout design is compared with one or more groups of layout units. In one example as shown in FIG. 7A, a row of layout units is selected as a reference layout design, and the layout-versus-layout comparison with the reference layout design is conducted about N times (instead of N× N times as in the method used in FIG. 5).

FIG. 7A is a schematic diagram of a layout design of an integrated circuit having a matrix of layout units in a matching zone 100, in accordance with some embodiments. In FIG. 7A, the layout units in the row 110 are selected together as a reference layout design. Each layout unit in the row 110 is checked with design rules for fatal rule violations. In response to a condition that each layout unit in the row 110 is free from fatal rule violations, the reference layout design (i.e., the row 110 of layout units) is compared with each row of layout units in the matching zone 100 to check for layout pattern consistency. In one example implementation, to check for layout pattern consistency, the reference layout design (i.e., the row 110 of layout units) is compared with the row 120, then with the row 130, then with the row 140, and last with the row 120. In some implementations, the checking of layout pattern consistency includes a symmetry operation performed on a chosen row of layout unit to be checked or performed on the reference layout design (i.e., the row 110 of layout units). Examples of the symmetry operation includes a translational symmetry operation, a reflection symmetry operation, a rotational symmetry operation, or a combination thereof.

While in some embodiments, such as in the example as shown in FIG. 7A, all layout units in a row (such as in the row 110) are selected together as a reference layout design, in some alternative embodiments, such as in the example as shown in FIG. 7B, a portion of the layout units in a row (such as in the row 710) are selected together a reference layout design.

FIG. 7B is a schematic diagram of a layout design of an integrated circuit having layout units arranged in multiple rectangular areas of a matching zone, in accordance with some embodiments. In FIG. 7B, the matching zone 700 having multiple layout units is an innermost matching zone surrounded by at least another matching zone which has different set of matching rules. The matching zone 700 has two layout areas R1 and R2. The layout units in the layout area R1 are arranged in a matrix which has 8 rows and 10 columns. The 8 rows of the matrix in the layout area R1 are rows 710-780, and the 10 columns of the matrix in the layout area R1 are columns 7C1-7C10. The layout units in the layout area R2 are arranged in a matrix which has 8 rows and 5 columns. The 8 rows of the matrix in the layout area R2 are rows 110-180, and the 5 columns of the matrix in the layout area R2 are aligned correspondingly with the columns 7C3-7C7 in the layout area R1.

In FIG. 7B, a group of five layout units in the row 710 is selected a reference layout design. Specifically, the layout units in the row 710 selected together as the reference layout design are the five layout units in columns 7C1-7C5. Each of the five layout units of the row 710 (in the columns 7C1-7C5) is checked with design rules for fatal rule violations. In response to a condition that each of the five layout units in the row 110 (in the columns 7C1-7C5) is free from fatal rule violations, the reference layout design (i.e., the five layout units in the row 710 and the columns 7C1-7C5) is repetitively compared with another group of five layout units, to check for layout pattern consistency, in both the layout area R1 and the layout area R2 in the matching zone 700. In some implementations, the checking of layout pattern consistency includes a symmetry operation performed on the group of five layout units to be checked or performed on the reference layout design (i.e., the five layout units in the row 710 in the columns 7C1-7C5). Examples of the symmetry operation includes a translational symmetry operation, a reflection symmetry operation, a rotational symmetry operation, or a combination thereof.

In one implementation, the following groups of five layout units are formed in the layout area R1 for comparing with the reference layout design: the group of five layout units in the columns 7C6-7C10 in the row 710, the group of five layout units in the columns 7C1-7C5 in each of the rows 720-780, and the group of five layout units in the columns 7C6-7C10 in each of the rows 720-780. In one implementation, the following groups of five layout units are formed in the layout area R2 for comparing with the reference layout design: the group of five layout units in the columns 7C3-7C7 in each of the rows 110-180 in the matrix of the layout area R2.

In the example implementation as shown in FIG. 7B, the reference layout design includes five layout units. Also, the ten layout units in each row in the layout area R1 are divided into two groups while each group has five layout units. For example, the ten layout units in the row 710 are divided into a first group of layout units in the columns 7C1-7C5 and a second group of layout units in the columns 7C6-7C10. The first group of layout units in the columns 7C1-7C5 in the row 710 is selected as the reference layout design. Similarly, the ten layout units in each of the rows 720-780 are also divided into a first group of layout units in the columns 7C1-7C5 and a second group of layout units in the columns 7C6-7C10. In each row, the first group of layout units and the second group of layout units are not overlapping with each other (that is, the first group and the second group do not share any common layout unit).

In some alternative implementations, it is possible that the first group and the second group share one or more common layout units. For example, in another example implementation, the layout units in the layout area R1 are arranged in a matrix which has nine columns 7C1-7C9 (which is not shown in a figure modified from FIG. 7B). The nine layout units in each row in the layout area R1 are divided into a first group of layout units in the columns 7C1-7C5 and a second group of layout units in the columns 7C5-7C9. Each of the first group and the second group still has five layout units, but the first group and the second group share one common layout unit in column 7C5. After the first group of layout units in the columns 7C1-7C5 in the row 710 is selected as the reference layout design, the reference layout design is compared with the first group of five layout units in each row of the matrix and compared with the second group of five layout units in each row of the matrix, to check for layout pattern consistency in the layout area R1.

In FIG. 5 and FIGS. 7A-7B, the layout-versus-layout comparison process as described for checking consistency sometimes includes a symmetry operation. Examples of the symmetry operation includes a translational symmetry operation, a reflection symmetry operation, a rotational symmetry operation, or a combination thereof. The symmetry operation in a layout-versus-layout comparison process is described in more details with reference to FIGS. 8A-8D.

FIGS. 8A-8D are schematic diagrams of layout designs of an integrated circuit having a matrix of layout units in a matching zone 800, in accordance with some embodiments. The matching zone 800 having multiple layout units is often surrounded by at least another matching zone which has different set of matching rules. In the example layout designs as shown in FIGS. 8A-8D, the matching zone 800 includes six rows of layout units 810-860, and each row includes seven layout units. The layout units in the matrix are arranged in seven columns 8C1-8C7.

In FIG. 8A, each layout unit maintains a translational symmetry with respect to another layout unit. With a translational symmetry operation, under a proper position shifting of a layout unit, the layout pattern of the layout unit shifted matches the layout pattern of another layout unit. In some implementations, the layout unit 811 in the row 810 and column 8C1 is selected as the reference layout design. During a layout-versus-layout comparison process, a chosen layout unit has the layout pattern consistency with respect to the reference layout design (i.e., the layout unit 811), if it is possible to match the layout pattern of the chosen layout unit with the layout pattern of the layout unit 811 under a translational symmetry operation in which a position of the chosen layout unit or the layout unit 811 is shifted.

In FIG. 8B, the layout pattern of each layout unit in the rows 820, 840, and 860 is a horizontal reflection (with respect to the X-axis) of the layout pattern of a layout unit in the rows 810, 830, or 850. With a horizontal reflection symmetry operation, under a proper position shifting, the layout pattern of a layout unit in the rows 820, 840, and 860 matches the layout pattern of another layout unit in the rows 810, 830, or 850. In some implementations, the layout unit 811 in the row 810 and column 8C1 is selected as the reference layout design. During a layout-versus-layout comparison process, a chosen layout unit in the rows 810, 830, or 850 has the layout pattern consistency with respect to the reference layout design, if it is possible to match the layout pattern of the chosen layout unit with the layout pattern of the layout unit 811 under a translational symmetry operation in which a position of the chosen layout unit or the layout unit 811 is shifted. A chosen layout unit in the rows 820, 840, or 860 has the layout pattern consistency with respect to the reference layout design, if it is possible to match the layout pattern of the chosen layout unit with the layout pattern of the layout unit 811 under a translational symmetry operation and a horizontal reflection symmetry operation which are performed either on the chosen layout unit or the layout unit 811.

In some alternative implementations, the layout units in the row 810 are selected together in a group as the reference layout design. During a layout-versus-layout comparison process, the layout units in the rows 830 or 850 have the layout pattern consistency with respect to the reference layout design, if it is possible to match the layout pattern of the rows 830 or 850 with the layout pattern of the row 810 under a translational symmetry operation. The layout units in the rows 820, 840, or 860 have the layout pattern consistency with respect to the reference layout design, if it is possible to match the layout pattern of the rows 820, 840, or 860 with the layout pattern of the row 810 under a translational symmetry operation and a horizontal reflection symmetry operation.

In FIG. 8C, the layout pattern of each layout unit in the columns 8C2, 8C4, and 8C6 is a vertical reflection (with respect to the Y-axis) of the layout pattern of a layout unit in the columns 8C1, 8C3, 8C5, or 8C7. With a vertical reflection symmetry operation, under a proper position shifting, the layout pattern of a layout unit in the columns 8C2, 8C4, and 8C6 matches the layout pattern of another layout unit in the columns 8C1, 8C3, 8C5, or 8C7. In some implementations, the layout unit 811 is selected as the reference layout design. During a layout-versus-layout comparison process, a chosen layout unit in the columns 8C1, 8C3, 8C5, or 8C7 has the layout pattern consistency with respect to the reference layout design, if it is possible to match the layout pattern of the chosen layout unit with the layout pattern of the layout unit 811 under a translational symmetry operation. A chosen layout unit in the columns 8C2, 8C4, and 8C6 has the layout pattern consistency with respect to the reference layout design, if it is possible to match the layout pattern of the chosen layout unit with the layout pattern of the layout unit 811 under a translational symmetry operation and a vertical reflection symmetry operation which are performed either on the chosen layout unit or the layout unit 811.

In some alternative implementations, the layout units in the column 8C1 are selected together in a group as the reference layout design. During a layout-versus-layout comparison process, the layout units in the columns 8C3, 8C5, or 8C7 have the layout pattern consistency with respect to the reference layout design, if it is possible to match the layout pattern of the columns 8C3, 8C5, or 8C7 with the layout pattern of the column 8C1 under a translational symmetry operation. The layout units in the columns 8C2, 8C4, or 8C6 have the layout pattern consistency with respect to the reference layout design, if it is possible to match the layout pattern of the columns 8C2, 8C4, or 8C6 with the layout pattern of the column 8C1 under a translational symmetry operation and a vertical reflection symmetry operation.

In FIG. 8D, with respect to the layout pattern of one entire row, each of the rows 810, 830, and 850 has a same first layout pattern of single-row, and each of the rows 820, 840, and 860 has a same second layout pattern of single-row. The second layout pattern of single-row for the rows 820, 840, and 860 is a horizontal reflection (with respect to the X-axis) of the first layout pattern of single-row for the rows 810, 830, or 850.

With respect to the layout pattern of one entire column, each of the columns 8C1, 8C3, 8C5, or 8C7 has a same first layout pattern of single-column, and each of the columns 8C2, 8C4, and 8C6 has a same second layout pattern of single-column. The second layout pattern of single-column for the columns 8C2, 8C4, and 8C6 is a vertical reflection (with respect to the Y-axis) of the first layout pattern of single-column for the columns 8C1, 8C3, 8C5, or 8C7.

With respect to the layout pattern of one layout unit, as examples, in the row 820 or the row 830, the layout pattern of each layout unit in the columns 8C1, 8C3, 8C5, and 8C7 is the same, the layout pattern of each layout unit in the columns 8C1, 8C3, 8C5, and 8C7 is the same. In the row 820 or the row 830, the layout pattern of each layout unit in the columns 8C2, 8C4, and 8C6 is a vertical reflection (with respect to the Y-axis) of the layout pattern of a layout unit in the columns 8C1, 8C3, 8C5, or 8C7.

In some implementations, the layout unit 811 of the row 810 is selected as the reference layout design. During a layout-versus-layout comparison process for checking the layout units in the row 830, a chosen layout unit in the columns 8C1, 8C3, 8C5, or 8C7 of the row 830 has the layout pattern consistency with respect to the reference layout design, if it is possible to match the layout pattern of the chosen layout unit with the layout pattern of the layout unit 811 under a translational symmetry operation. In addition, a chosen layout unit in the columns 8C2, 8C4, and 8C6 of the row 830 has the layout pattern consistency with respect to the reference layout design, if it is possible to match the layout pattern of the chosen layout unit with the layout pattern of the layout unit 811 under a translational symmetry operation and a vertical reflection symmetry operation.

During a layout-versus-layout comparison process for checking the layout units in the row 820, a chosen layout unit in the columns 8C1, 8C3, 8C5, or 8C7 of the row 820 has the layout pattern consistency with respect to the reference layout design, if it is possible to match the layout pattern of the chosen layout unit with the layout pattern of the layout unit 811 (as the reference layout design) under a translational symmetry operation and a horizontal reflection symmetry operation. In addition, a chosen layout unit in the columns 8C2, 8C4, and 8C6 of the row 820 has the layout pattern consistency with respect to the reference layout design, if it is possible to match the layout pattern of the chosen layout unit with the layout pattern of the layout unit 811 (as the reference layout design) under a translational symmetry operation, a horizontal reflection symmetry operation, and a vertical reflection symmetry operation. Equivalently, a chosen layout unit in the columns 8C2, 8C4, and 8C6 of the row 820 has the layout pattern consistency with respect to the reference layout design, if it is possible to match the layout pattern of the chosen layout unit with the layout pattern of the layout unit 811 (as the reference layout design) under a translational symmetry operation and a rotational symmetry operation of 180 degrees.

In some alternative implementations, the layout units in the row 810 are selected together in a group as the reference layout design. During a layout-versus-layout comparison process, the rows 830 or 850 have the layout pattern consistency with respect to the reference layout design, if it is possible to match the layout pattern of the rows 830 or 850 with the layout pattern of the row 810 under a translational symmetry operation. The rows 820, 840, or 860 have the layout pattern consistency with respect to the reference layout design, if it is possible to match the layout pattern of the rows 820, 840, or 860 with the layout pattern of the row 810 under a translational symmetry operation and a horizontal reflection symmetry operation.

In still some alternative implementations, the layout units in the column 8C1 are selected together in a group as the reference layout design. During a layout-versus-layout comparison process, the columns 8C3, 8C5, or 8C7 have the layout pattern consistency with respect to the reference layout design, if it is possible to match the layout pattern of the columns 8C3, 8C5, or 8C7 with the layout pattern of the column 8C1 under a translational symmetry operation. The columns 8C2, 8C4, and 8C6 have the layout pattern consistency with respect to the reference layout design, if it is possible to match the layout pattern of the columns 8C2, 8C4, and 8C6 with the layout pattern of the column 8C1 under a translational symmetry operation and a vertical reflection symmetry operation.

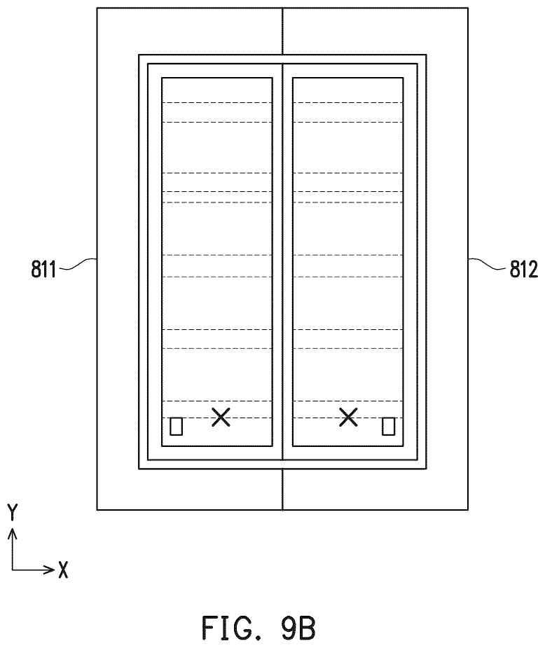

For checking layout pattern consistency between two layout units in the matrix as shown in FIGS. 8A-8D, in some implementations, a layout-versus-layout comparison process involves matching the layout patterns of the two layout units with a symmetry operation such as a horizontal reflection symmetry operation or a vertical reflection symmetry operation. The process of matching the layout patterns with a horizontal reflection symmetry operation or a vertical reflection symmetry operation is explained in more details correspondingly in FIG. 9A and FIG. 9B.

FIG. 9A is a schematic diagram of two layout units having layout pattern consistency under a horizontal reflection symmetry operation, in accordance with some embodiments. In FIG. 9A, the layout pattern of a layout unit 811 matches the layout pattern of a layout unit 821 if a horizontal reflection symmetry operation (with respect to the X-axis) is performed on either the layout unit 811 or the layout unit 821.

FIG. 9B is a schematic diagram of two layout units having layout pattern consistency under a vertical reflection symmetry operation, in accordance with some embodiments. In FIG. 9B, the layout pattern of a layout unit 811 matches the layout pattern of a layout unit 812 if a vertical reflection symmetry operation (with respect to the Y-axis) is performed on either the layout unit 811 or the layout unit 812.

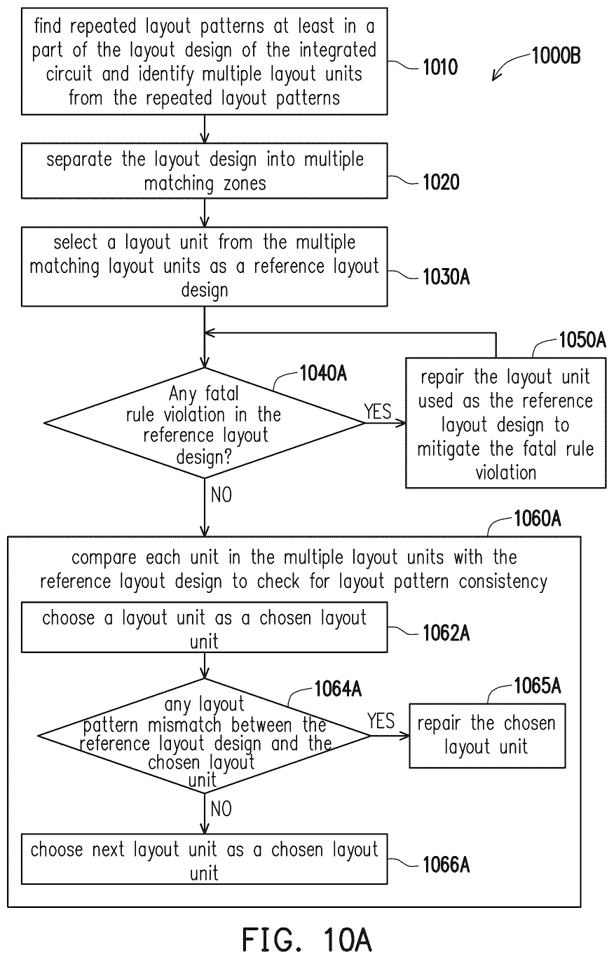

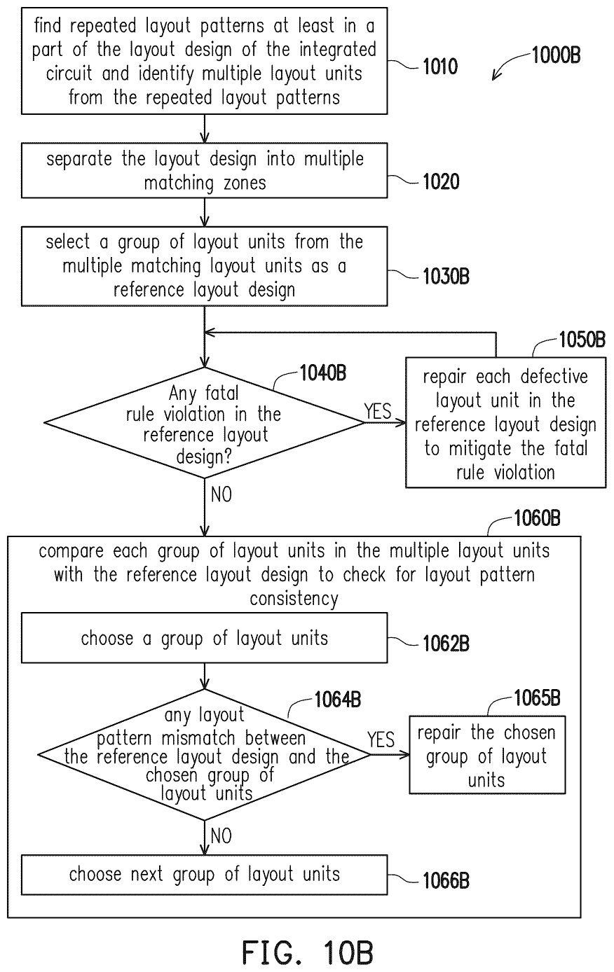

FIGS. 10A-10B are flowcharts of methods 1000A-1000B of processing a layout design of an integrated circuit, in accordance with some embodiments. The sequence in which the operations of each of the methods 1000A-1000B are depicted in FIGS. 10A-10B is for illustration only; the operations each of the methods 1000A-1000B are capable of being executed in sequences that differ from that depicted FIGS. 10A-10B. It is understood that additional operations may be performed before, during, and/or after each of the methods 1000A-1000B, and that some other processes may only be briefly described herein.

The method 1000A as depicted in the flow chart of FIG. 10A includes operations 1010-1020 and 1030A-1060A. In operation 1010 of the method 1000A, repeated layout patterns are searched in the layout design of the integrated circuit and multiple layout units are identified from the repeated layout patterns. In some embodiments as shown in FIG. 1 and FIG. 5, the layout units 111-115, 121-125, 131-135, 141-145, and 151-155 are identified from the repeated layout patterns in the layout design.

In operation 1020 of the method 1000A, the layout design is separated into multiple matching zones. The multiple layout units identified from the repeated layout patterns are in an inner matching zone which has more matching rules than other matching zones surrounding the inner matching zone. In some embodiments as shown in FIG. 1 and FIG. 5, the multiple matching zones in the layout design include matching zones 100, 102, and 103. The layout units 111-115, 121-125, 131-135, 141-145, and 151-155 are all in the matching zone 100.

In operation 1030A of the method 1000A, one layout unit is selected from the multiple matching layout units as a reference layout design. In some embodiments as shown in FIG. 1 and FIG. 5, the layout unit 111 in the row 110 is selected as a reference layout design.

In operation 1040A of the method 1000A, the reference layout design is checked for a fatal rule violation. In response to the reference layout design being free from any fatal rule violation, the process flow proceeds to operation 1060A. In response to the reference layout design having a fatal rule violation, the process flow proceeds to operation 1050A. In some embodiments as shown in FIG. 1 and FIG. 5, the layout unit 111 in the row 110 is checked for a fatal rule violation.

In operation 1050A of the method 1000A, because the layout unit used as the reference layout design is found to have a fatal rule violation during operation 1040A, the corresponding layout unit (i.e., the reference layout design) is repaired to mitigate the fatal rule violation. After the reference layout design is repaired, the process flow reurns to operation 1040A, and the reference layout design is checked again for a fatal rule violation. In some embodiments as shown in FIG. 1 and FIG. 5, if the layout unit 111 in the row 110 is found to have a fatal rule violation, the layout unit 111 is then repaired, and after the repairing, the layout unit 111 in the row 110 is checked again for any fatal rule violation.

In operation 1060A of the method 1000A, each layout unit in the multiple layout units is compared with the reference layout design to check for layout pattern consistency. In some embodiments as shown in FIG. 1 and FIG. 5, each of the layout units is compared with 112-115, 121-125, 131-135, 141-145, and 151-155 is compared with the layout unit 111 (which is the reference layout design) to check for layout pattern consistency.

More specifically, in FIG. 10A, the execution of operation 1060A further includes executing operations 1062A, 1064A, 1065A, and 1066A. In operation 1062A, a layout unit is chosen as a chosen layout unit. In operation 1064A, the chosen layout unit is compared with the reference layout design (such as the layout unit 111) to check for layout pattern consistency. After operation 1064A, in response to a finding that certain layout pattern mismatch exits between the chosen layout unit and the reference layout design (e.g., the layout unit 111), the defect in the chosen layout unit is repaired in operation 1065A. After the chosen layout unit is repaired, the process flow returns to operation 1064A. Alternatively, after operation 1064A, in response to a finding that the chosen layout unit and the reference layout design (e.g., the layout unit 111) have layout pattern consistency, the process flow proceeds to operation 1066A. In operation 1066A, next layout unit is chosen as a chosen layout unit, and the process flow returns to operation 1064A.

In method 1000A, a single layout unit is selected as a reference layout design for further checking on layout pattern consistency with another layout unit. As alternatives, in method 1000B, a group of layout units is selected as a reference layout design for further checking on layout pattern consistency with another group of layout units. The method 1000B as depicted in the flow chart of FIG. 10B includes operations 1010-1020 and 1030B-1060B.

Operations 1010-1020 in the method 1000B are executed the same way as operations 1010-1020 in the method 1000A. Operations 1030B-1060B in the method 1000B, however, are executed differently than operations 1030A-1060A in the method 1000A.

In operation 1030B of the method 1000B, a group of layout units is selected from the multiple matching layout units as a reference layout design. In some embodiments as shown in FIG. 7A, the layout units in the row 110 are selected together in a group as a reference layout design. In some embodiments as shown in FIG. 7B, the five layout units of the row 710 in columns 7C1-7C5 are selected together in a group as a reference layout design.

In operation 1040B of the method 1000B, the reference layout design is checked for a fatal rule violation. More Specifically, each layout unit in the reference layout design, because the reference layout design includes a group of layout units. In response to the reference layout design being free from any fatal rule violation, the process flow proceeds to operation 1060B. In response to the reference layout design having a fatal rule violation in at least one layout unit, the process flow proceeds to operation 1050B. In some embodiments as shown in FIG. 7A, each layout unit in the row 110 is checked for a fatal rule violation. In some embodiments as shown in FIG. 7B, each of the five layout units of the row 710 in columns 7C1-7C5 is checked for a fatal rule violation.

In operation 1050B of the method 1000B, because at least one layout unit in the reference layout design is found to have a fatal rule violation during operation 1040B, each defective layout unit in the reference layout design is repaired to mitigate the fatal rule violation. After the reference layout design is repaired, the process flow returns to operation 1040B, and the reference layout design is checked again for a fatal rule violation. In some embodiments as shown in FIG. 7A, each layout unit (in the row 110) which has a fatal rule violation is repaired in operation 1050B. In some embodiments as shown in FIG. 7B, each layout unit (in the row 710 and in columns 7C1-7C5) which has a fatal rule violation is repaired in operation 1050B.

In operation 1060B of the method 1000B, each group of layout units in the multiple layout units is compared with the reference layout design to check for layout pattern consistency. In some embodiments as shown in FIG. 7A, the layout units in the row 110 as a group is the reference layout design, and the layout pattern of the row 110 is compared with the layout pattern of each row from rows 120-150.

More specifically, in FIG. 10B, the execution of operation 1060B further includes executing operations 1062B, 1064B, 1065B, and 1066B. In operation 1062B, a group of layout units is chosen as a chosen group of layout units. In operation 1064B, the chosen group of layout units is compared with the reference layout design to check for layout pattern consistency. After operation 1064B, in response to a finding that certain layout pattern mismatch exits between the chosen group of layout units and the reference layout design, each defective layout unit in the chosen group of layout units is repaired in operation 1065B. After the chosen group of layout units is repaired, the process flow returns to operation 1064B. Alternatively, after operation 1064B, in response to a finding that the chosen group of layout units and the reference layout design have layout pattern consistency, the process flow proceeds to operation 1066B. In operation 1066B, next group of layout units is chosen as a chosen group of layout units, and the process flow returns to operation 1064B.

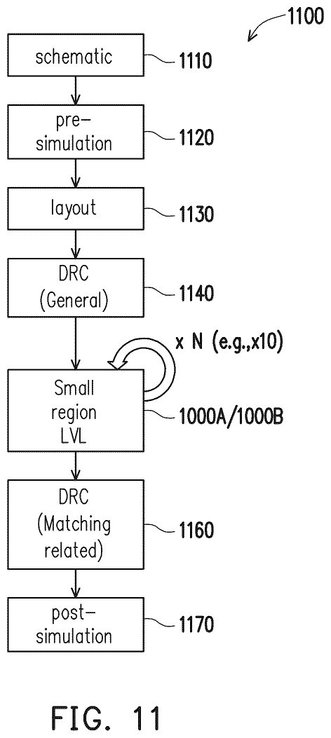

An example of executing the methods 1000A or 1000B in a design flow process is depicted in a flowchart in FIG. 11. In FIG. 11, a method 1100 includes operations 1110-1140, operation 1000A/1000B, and operations 1160-1170. In operation 1110, a schematic of an integrated circuit is created. The schematic of the integrated circuit is simulated in operation 1120 with a simulation/modeling program (such as the SPICE simulator). Then, in operation 1130, a layout design of the integrated circuit is created. Thereafter, general design rule check (DRC) is conducted in operation 1140. After that, the design flow process proceeds to operation 1000A/1000B.

In operation 1000A/1000B, regions of the layout design are checked for errors based on layout-versus-layout (“LVL”) comparison process, and the errors discovered in LVL comparison process are corrected. The error discovering operation and the error correction operation are repeated multiple times (such as 10 times). In some embodiments, operation 1000A/1000B are conducted based on the method 1000A depicted in FIG. 10A or the method 1000B depicted in FIG. 10B. Thereafter, in operation 1160, matching related design rule check (DRC) is conducted, and post simulation is conducted in operation 1170.

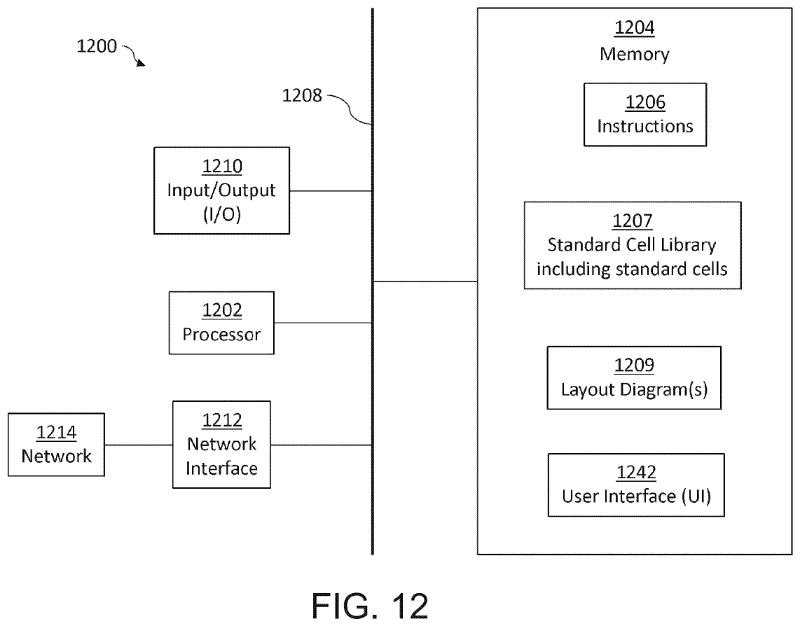

FIG. 12 is a block diagram of an electronic design automation (EDA) system 1200 in accordance with some embodiments.

In some embodiments, EDA system 1200 includes an automatic placement and routing (APR) system. Methods described herein of designing layout diagrams represent wire routing arrangements, in accordance with one or more embodiments, are implementable, for example, using EDA system 1200, in accordance with some embodiments.

In some embodiments, EDA system 1200 is a general purpose computing device including a hardware processor 1202 and a non-transitory, computer-readable storage medium 1204. Storage medium 1204, amongst other things, is encoded with, i.e., stores, computer program code 1206, i.e., a set of executable instructions. Execution of instructions 1206 by hardware processor 1202 represents (at least in part) an EDA tool which implements a portion or all of the methods described herein in accordance with one or more embodiments (hereinafter, the noted processes and/or methods).

Processor 1202 is electrically coupled to computer-readable storage medium 1204 via a bus 1208. Processor 1202 is also electrically coupled to an I/O interface 1210 by bus 1208. A network interface 1212 is also electrically connected to processor 1202 via bus 1208. Network interface 1212 is connected to a network 1214, so that processor 1202 and computer-readable storage medium 1204 are capable of connecting to external elements via network 1214. Processor 1202 is configured to execute computer program code 1206 encoded in computer-readable storage medium 1204 in order to cause system 1200 to be usable for performing a portion or all of the noted processes and/or methods. In one or more embodiments, processor 1202 is a central processing unit (CPU), a multi-processor, a distributed processing system, an application specific integrated circuit (ASIC), and/or a suitable processing unit.

In one or more embodiments, computer-readable storage medium 1204 is an electronic, magnetic, optical, electromagnetic, infrared, and/or a semiconductor system (or apparatus or device). For example, computer-readable storage medium 1204 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1204 includes a compact disk-read only memory (CD-ROM), a compact disk-read/write (CD-R/W), and/or a digital video disc (DVD).

In one or more embodiments, storage medium 1204 stores computer program code 1206 configured to cause system 1200 (where such execution represents (at least in part) the EDA tool) to be usable for performing a portion or all of the noted processes and/or methods. In one or more embodiments, storage medium 1204 also stores information which facilitates performing a portion or all of the noted processes and/or methods. In one or more embodiments, storage medium 1204 stores library 1207 of standard cells including such standard cells as disclosed herein. In one or more embodiments, storage medium 1204 stores one or more layout diagrams 1209 corresponding to one or more layouts disclosed herein.

EDA system 1200 includes I/O interface 1210. I/O interface 1210 is coupled to external circuitry. In one or more embodiments, I/O interface 1210 includes a keyboard, keypad, mouse, trackball, trackpad, touchscreen, and/or cursor direction keys for communicating information and commands to processor 1202.

EDA system 1200 also includes network interface 1212 coupled to processor 1202. Network interface 1212 allows system 1200 to communicate with network 1214, to which one or more other computer systems are connected. Network interface 1212 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1200.

System 1200 is configured to receive information through I/O interface 1210. The information received through I/O interface 1210 includes one or more of instructions, data, design rules, libraries of standard cells, and/or other parameters for processing by processor 1202. The information is transferred to processor 1202 via bus 1208. EDA system 1200 is configured to receive information related to a user interface (UI) through I/O interface 1210. The information is stored in computer-readable medium 1204 as UI 1242.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1200. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

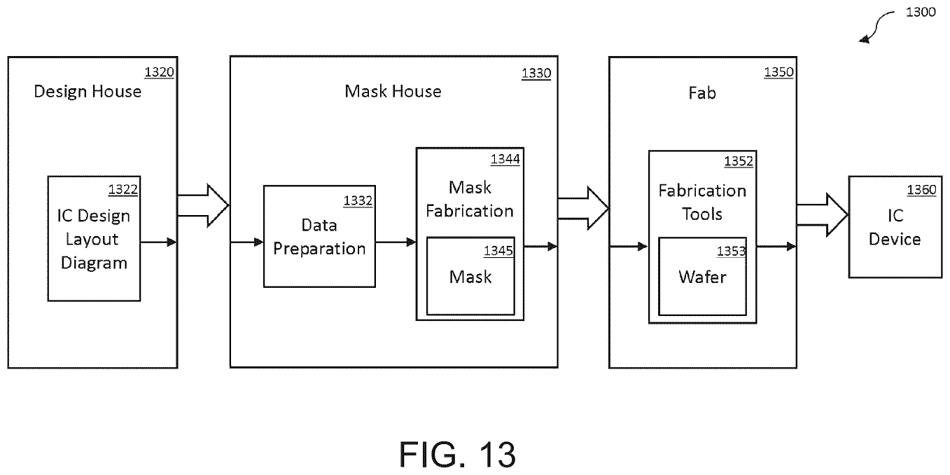

FIG. 13 is a block diagram of an integrated circuit (IC) manufacturing system 1300, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1300.

In FIG. 13, IC manufacturing system 1300 includes entities, such as a design house 1320, a mask house 1330, and an IC manufacturer/fabricator (fab) 1350, that interact with one another in the design, development, and manufacturing cycles and/or services related to manufacturing an IC device 1360. The entities in system 1300 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1320, mask house 1330, and IC fab 1350 is owned by a single larger company. In some embodiments, two or more of design house 1320, mask house 1330, and IC fab 1350 coexist in a common facility and use common resources.

Design house (or design team) 1320 generates an IC design layout diagram 1322. IC design layout diagram 1322 includes various geometrical patterns designed for an IC device 1360. The geometrical patterns correspond to patterns of metal, oxide, or semiconductor layers that make up the various components of IC device 1360 to be fabricated. The various layers combine to form various IC features. For example, a portion of IC design layout diagram 1322 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1320 implements a proper design procedure to form IC design layout diagram 1322. The design procedure includes one or more of logic design, physical design or place and route. IC design layout diagram 1322 is presented in one or more data files having information of the geometrical patterns. For example, IC design layout diagram 1322 can be expressed in a GDSII file format or DFII file format.

Mask house 1330 includes data preparation 1332 and mask fabrication 1344. Mask house 1330 uses IC design layout diagram 1322 to manufacture one or more masks 1345 to be used for fabricating the various layers of IC device 1360 according to IC design layout diagram 1322. Mask house 1330 performs mask data preparation 1332, where IC design layout diagram 1322 is translated into a representative data file (RDF). Mask data preparation 1332 provides the RDF to mask fabrication 1344. Mask fabrication 1344 includes a mask writer. A mask writer converts the RDF to an image on a substrate, such as a mask (reticle) 1345 or a semiconductor wafer 1353. The design layout diagram 1322 is manipulated by mask data preparation 1332 to comply with particular characteristics of the mask writer and/or requirements of IC fab 1350. In FIG. 13, mask data preparation 1332 and mask fabrication 1344 are illustrated as separate elements. In some embodiments, mask data preparation 1332 and mask fabrication 1344 can be collectively referred to as mask data preparation.

In some embodiments, mask data preparation 1332 includes optical proximity correction (OPC) which uses lithography enhancement techniques to compensate for image errors, such as those that can arise from diffraction, interference, other process effects and the like. OPC adjusts IC design layout diagram 1322. In some embodiments, mask data preparation 1332 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1332 includes a mask rule checker (MRC) that checks the IC design layout diagram 1322 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1322 to compensate for photolithographic implementation effects during mask fabrication 1344, which may undo part of the modifications performed by OPC in order to meet mask creation rules.

In some embodiments, mask data preparation 1332 includes lithography process checking (LPC) that simulates processing that will be implemented by IC fab 1350 to fabricate IC device 1360. LPC simulates this processing based on IC design layout diagram 1322 to create a simulated manufactured device, such as IC device 1360. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1322.

It should be understood that the above description of mask data preparation 1332 has been simplified for the purposes of clarity. In some embodiments, data preparation 1332 includes additional features such as a logic operation (LOP) to modify the IC design layout diagram 1322 according to manufacturing rules. Additionally, the processes applied to IC design layout diagram 1322 during data preparation 1332 may be executed in a variety of different orders.

After mask data preparation 1332 and during mask fabrication 1344, a mask 1345 or a group of masks 1345 are fabricated based on the modified IC design layout diagram 1322. In some embodiments, mask fabrication 1344 includes performing one or more lithographic exposures based on IC design layout diagram 1322. In some embodiments, an electron-beam (e-beam) or a mechanism of multiple e-beams is used to form a pattern on a mask (photomask or reticle) 1345 based on the modified IC design layout diagram 1322. Mask 1345 can be formed in various technologies. In some embodiments, mask 1345 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1345 includes a transparent substrate (e.g., fused quartz) and an opaque material (e.g., chromium) coated in the opaque regions of the binary mask. In another example, mask 1345 is formed using a phase shift technology. In a phase shift mask (PSM) version of mask 1345, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1344 is used in a variety of processes. For example, such a mask(s) is used in an ion implantation process to form various doped regions in semiconductor wafer 1353, in an etching process to form various etching regions in semiconductor wafer 1353, and/or in other suitable processes.

IC fab 1350 is an IC fabrication business that includes one or more manufacturing facilities for the fabrication of a variety of different IC products. In some embodiments, IC Fab 1350 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1350 includes fabrication tools 1352 configured to execute various manufacturing operations on semiconductor wafer 1353 such that IC device 1360 is fabricated in accordance with the mask(s), e.g., mask 1345. In various embodiments, fabrication tools 1352 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1350 uses mask(s) 1345 fabricated by mask house 1330 to fabricate IC device 1360. Thus, IC fab 1350 at least indirectly uses IC design layout diagram 1322 to fabricate IC device 1360. In some embodiments, semiconductor wafer 1353 is fabricated by IC fab 1350 using mask(s) 1345 to form IC device 1360. In some embodiments, the IC fabrication includes performing one or more lithographic exposures based at least indirectly on IC design layout diagram 1322. Semiconductor wafer 1353 includes a silicon substrate or other proper substrate having material layers formed thereon. Semiconductor wafer 1353 further includes one or more of various doped regions, dielectric features, multilevel interconnects, and the like (formed at subsequent manufacturing steps).

One aspect of this description relates to a method of processing a layout design of an integrated circuit. The method includes finding repeated layout patterns at least in a part of the layout design of the integrated circuit and identifying multiple layout units from the repeated layout patterns, the multiple layout units including a first layout unit and a second layout unit; separating the layout design into multiple matching zones, and where at least two of the matching zones have different sets of matching rules, and where each of the multiple layout units is in a first matching zone; and comparing the first layout unit with the second layout unit and checking layout pattern consistency between the first layout unit and the second layout unit.

Another aspect of this description relates to a system for manufacturing an integrated circuit. The system includes a non-transitory computer readable medium configured to store executable instructions. The system also includes a processor coupled to the non-transitory computer readable medium, where the processor is configured to execute instructions for: finding repeated layout patterns at least in a part of a layout design of the integrated circuit and identifying multiple layout units from the repeated layout patterns, the multiple layout units including a first layout unit and a second layout unit; separating the layout design into multiple matching zones, and where at least two of the matching zones have different sets of matching rules, and where each of the multiple layout units is in a first matching zone; and comparing the first layout unit with the second layout unit and checking layout pattern consistency between the first layout unit and the second layout unit.

Still another aspect of this description relates to a non-transitory computer readable medium configured to store executable instructions. The non-transitory computer readable medium includes finding repeated layout patterns at least in a part of a layout design of an integrated circuit and identifying multiple layout units from the repeated layout patterns, the multiple layout units including a first layout unit and a second layout unit; separating the layout design into multiple matching zones, and where at least two of the matching zones have different sets of matching rules, and where each of the multiple layout units is in a first matching zone; and comparing the first layout unit with the second layout unit and checking layout pattern consistency between the first layout unit and the second layout unit.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

What is claimed is:

1. A method of processing, by a processor, a layout design of an integrated circuit, the method comprising:
finding repeated layout patterns at least in a part of the layout design of the integrated circuit and identifying multiple layout units from the repeated layout patterns, the multiple layout units including a first layout unit and a second layout unit;
separating the layout design into multiple matching zones, and wherein at least two of the matching zones have different sets of matching rules, and wherein each of the multiple layout units is in a first matching zone; and
comparing the first layout unit with the second layout unit and checking layout pattern consistency between the first layout unit and the second layout unit.

2. The method of claim 1, wherein comparing the first layout unit with the second layout unit comprises:
comparing the first layout unit with the second layout unit based on one of a translational symmetry operation, a reflection symmetry operation, or a rotational symmetry operation on the first layout unit or the second layout unit.

3. The method of claim 1, wherein each of the first layout unit with the second layout unit is a circuit layout design of a same electric circuit in the integrated circuit.

4. The method of claim 1, comprising:
selecting one layout unit from the multiple layout units as a reference layout design; and
comparing each layout unit in the multiple layout units with the reference layout design based on one of a translational symmetry operation, a reflection symmetry operation, or a rotational symmetry operation.

5. The method of claim 4, comprising:
checking the reference layout design for a fatal rule violation before comparing a layout unit in the multiple layout units with the reference layout design.

6. The method of claim 1, comprising:
selecting a first layout design of a first group of layout units in the multiple layout units as a reference layout design; and
comparing a second layout design of a second group of layout units in the multiple layout units with the reference layout design based on one of a translational symmetry operation, a reflection symmetry operation, or a rotational symmetry operation.

7. The method of claim 6, comprising:
checking the reference layout design for a fatal rule violation before comparing the second layout design with the reference layout design.

8. The method of claim 6, wherein the multiple layout units include a matrix of layout units, and wherein the first group of layout units is a first row of layout units in the matrix, and the second group of layout units is a second row of layout units in the matrix.

9. The method of claim 6, wherein the multiple layout units include a matrix of layout units having at least a first row of layout units and a second row of layout units, and wherein the first group of layout units is a portion of the first row of layout units, and the second group of layout units is a portion of the second row of layout units.

10. The method of claim 1, wherein the multiple layout units include a matrix of layout units, comprising:
selecting a first layout design of a first row of layout units as a reference layout design; and
selecting each row of layout units as a second group of layout units, and comparing a second layout design of the second group of layout units with the reference layout design based on one of a translational symmetry operation, a reflection symmetry operation, or a rotational symmetry operation.

11. The method of claim 1, wherein separating the layout design into the multiple matching zones comprises:
separating the layout design at least into the first matching zone, a second matching zone, and a third matching zone, wherein each matching rule for the third matching zone is also a matching rule for the first matching zone while at least one matching rule for the first matching zone is not a matching rule for the third matching zone.

12. The method of claim 11, wherein each matching rule for the third matching zone is also a matching rule for the second matching zone while at least one matching rule for the first matching zone is not a matching rule for the second matching zone.

13. The method of claim 11, wherein the first matching zone is surrounded by the second matching zone, and the second matching zone is surrounded by the third matching zone.

14. The method of claim 11, wherein each of the first matching zone, the second matching zone, and the third matching zone has an outer boundary with a shape of a rectangular, a circular, or a polygon.

15. A system for manufacturing an integrated circuit, the system comprises:
a non-transitory computer readable medium configured to store executable instructions; and
a processor coupled to the non-transitory computer readable medium, wherein the processor is configured to execute instructions for:
finding repeated layout patterns at least in a part of a layout design of the integrated circuit and identifying multiple layout units from the repeated layout patterns, the multiple layout units including a first layout unit and a second layout unit;
separating the layout design into multiple matching zones, and wherein at least two of the matching zones have different sets of matching rules, and wherein each of the multiple layout units is in a first matching zone; and
comparing the first layout unit with the second layout unit and checking layout pattern consistency between the first layout unit and the second layout unit.

16. The system of claim 15, wherein the processor is configured to execute further instructions for:
comparing the first layout unit with the second layout unit based on one of a translational symmetry operation, a reflection symmetry operation, or a rotational symmetry operation.

17. The system of claim 15, wherein the processor is configured to execute further instructions for:
selecting one layout unit from the multiple layout units as a reference layout design; and
comparing each layout unit in the multiple layout units with the reference layout design based on one of a translational symmetry operation, a reflection symmetry operation, or a rotational symmetry operation.

18. The system of claim 15, wherein the processor is configured to execute further instructions for:
selecting a first layout design of a first group of layout units in the multiple layout units as a reference layout design; and
comparing a second layout design of a second group of layout units in the multiple layout units with the reference layout design based on one of a translational symmetry operation, a reflection symmetry operation, or a rotational symmetry operation.

19. A non-transitory computer readable medium configured to store executable instructions, wherein the executable instructions are configured to be executed by a processor coupled to the non-transitory computer readable medium and to cause the processor to perform operations comprising:
finding repeated layout patterns at least in a part of a layout design of an integrated circuit and identifying multiple layout units from the repeated layout patterns, the multiple layout units including a first layout unit and a second layout unit;
separating the layout design into multiple matching zones, and wherein at least two of the matching zones have different sets of matching rules, and wherein each of the multiple layout units is in a first matching zone; and
comparing the first layout unit with the second layout unit and checking layout pattern consistency between the first layout unit and the second layout unit.

20. The non-transitory computer readable medium of claim 19, wherein the operations performed with the processor further comprises:
comparing the first layout unit with the second layout unit based on one of a translational symmetry operation, a reflection symmetry operation, or a rotational symmetry operation.
